(19) United States
(12) Patent Application Publication
(10) Pub. No.: US 2024/0249922 A1
(43) Pub. Date: Jul. 25, 2024

(54) PLASMA PROCESSING APPARATUS

(71) Applicant: Tokyo Electron Limited, Tokyo (JP)

(72) Inventor: Ryota SAKANE, Miyagi (JP)

(73) Assignee: Tokyo Electron Limited, Tokyo (JP)

(21) Appl. No.: 18/628,349

(22) Filed: Apr. 5, 2024

Related U.S. Application Data
(63) Continuation of application No. PCT/JP2022/035586, filed on Sep. 26, 2022.

(30) Foreign Application Priority Data
Oct. 8, 2021 (JP) 2021-165952

(51) Int. Cl. H01J 37/32

(52) U.S. Cl. CPC H01J 37/3255; H01J 37/32091; H01J 37/32559; H01J 37/32651; H01J 37/32577; H01J 2237/327

(57) ABSTRACT

A plasma processing apparatus includes a chamber, a power source, a silicon member, and a conductive film. The chamber provides a plasma processing space. The power source supplies radio-frequency power for generating plasma in the plasma processing space. The silicon member is made of a silicon-containing material, is disposed in the chamber, and has a first surface facing the plasma processing space. The conductive film is made of a conductive material and formed on a second surface that does not face the plasma processing space of the silicon member.

### CROSS-REFERENCE TO RELATED APPLICATIONS

This application is a bypass continuation application of international application No. PCT/JP2022/035586 having an international filing date of Sep. 26, 2022 and designating the United States, the international application being based upon and claiming the benefit of priority from Japanese Patent Application No. 2021-165952, filed on Oct. 8, 2021, the entire contents of each are incorporated herein by reference.

### TECHNICAL FIELD

The present disclosure relates to a plasma processing apparatus.

### BACKGROUND

Conventionally, there has been a plasma processing apparatus in which a deposition shield made of a metal such as aluminum is provided along an inner wall surface of a sidewall of a chamber that provides a plasma processing space (see Patent Document 1).

### CITATION LIST

### Patent Documents

Patent Document 1: JP2001-203189A

### SUMMARY

The present disclosure provides a technique capable of reducing a loss of radio-frequency power in a silicon member facing a plasma processing space.

A plasma processing apparatus according to an aspect of the present disclosure includes a chamber, a power source, a silicon member, and a conductive film. The chamber provides a plasma processing space. The power source supplies radio-frequency power for generating plasma in the plasma processing space. The silicon member is made of a silicon-containing material, is disposed in the chamber, and has a first surface facing the plasma processing space. The conductive film is made of a conductive material and formed on a second surface that does not face the plasma processing space of the silicon member.

According to the present disclosure, it is possible to reduce a loss of radio-frequency power in the silicon member facing the plasma processing space.

### BRIEF DESCRIPTION OF DRAWINGS

FIG. 1 is a view illustrating a configuration example of a capacitively-coupled plasma processing apparatus according to an embodiment.

FIG. 2 is a diagram schematically illustrating an example of a structure of a silicon member in an embodiment.

FIG. 3 is a diagram schematically illustrating another example of the structure of the silicon member in the embodiment.

FIG. 4 is a view illustrating an example of a specific configuration of forming a conductive film on a second surface of a deposition shield according to the embodiment.

FIG. 5 is a view illustrating an example of a specific configuration of forming a conductive film on a second surface of an electrode plate of a shower head according to the embodiment.

FIG. 6 is a view illustrating an example of occurrence of a gap in the shower head according to the embodiment.

### DETAILED DESCRIPTION

Hereinafter, embodiments of a plasma processing apparatus disclosed in the present application will be described in detail with reference to the drawings. The present embodiment is not limited to the plasma processing apparatus.

A deposition shield made of metal may generate particles by being exposed to plasma in a chamber. Meanwhile, instead of the deposition shield made of a metal, it has been investigated to use a deposition shield made of, for example, a silicon-containing material such as silicon, silicon carbide, silicon dioxide, or silicon nitride. Since the silicon-containing material is vaporized in plasma, the generation of particles can be suppressed.

However, the silicon-containing material has a higher resistance value than metal. Therefore, in the plasma processing apparatus using the deposition shield made of the silicon-containing material, when radio-frequency power is supplied from a radio-frequency power source into a plasma processing space in order to generate plasma, a loss of radio-frequency power in the deposition shield may increase.

Further, in the plasma processing apparatus, in addition to the deposition shield, a silicon member made of a silicon-containing material may be used for other members facing the plasma processing space. For example, in the plasma processing apparatus, a silicon-containing material may be used for a baffle plate, an electrode plate of an upper electrode, or the shutter. Similar to the deposition shield, the silicon member facing the plasma processing space may also generate radio-frequency power loss.

Therefore, a technique capable of reducing the loss of the radio-frequency power in the silicon member facing the plasma processing space is expected.

### EMBODIMENT

### Configuration of Plasma Processing System

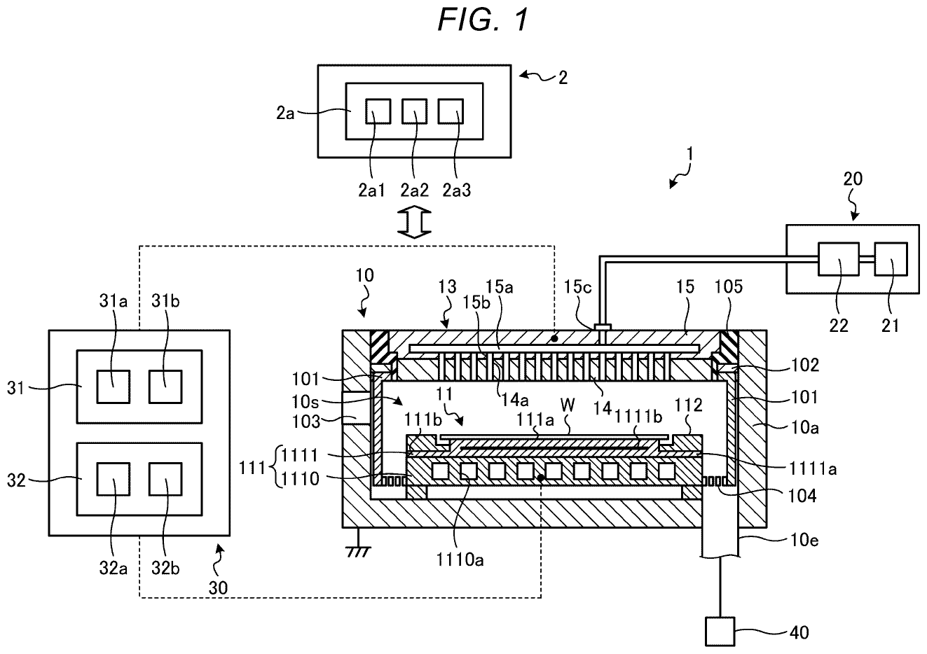

Hereinafter, a configuration example of a plasma processing system will be described. FIG. 1 is a view illustrating a configuration example of a capacitively-coupled plasma processing apparatus according to an embodiment.

The plasma processing system includes a capacitively-coupled plasma processing apparatus 1 and a controller 2. The capacitively-coupled plasma processing apparatus 1 includes a plasma processing chamber 10, a gas supply 20, a power source 30, and an exhaust system 40. Further, the plasma processing apparatus 1 includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 has at least one gas supply port for supplying at least one processing gas into the plasma processing space 10s, and at least one gas exhaust port for exhausting the gas from the plasma processing space 10s. The sidewall 10a of the plasma processing chamber 10 is grounded. The shower head 13 and the substrate support 11 are electrically insulated from a housing of the plasma processing chamber 10.

A deposition shield 101 is provided on an inner wall surface of the sidewall 10a of the plasma processing chamber 10 with a gap between the sidewall 10a and the inner wall surface. The deposition shield 101 is a silicon member made of a silicon-containing material and faces the plasma processing space 10s. As the silicon-containing material configuring the deposition shield 101, for example, silicon (Si), silicon carbide (SiC), silicon dioxide (SiO₂), silicon nitride (Si3N4), or the like can be used. The upper portion of the deposition shield 101 is bent inward in a horizontal direction, and is in contact with a conductive grounding member 102 provided in the sidewall 10a of the plasma processing chamber 10. Further, a loading/unloading port 103 for loading and unloading a substrate W is provided in the sidewall 10a, and an openable/closable shutter (not illustrated) is provided at a position corresponding to the loading/unloading port 103 of the deposition shield 101. In the example of FIG. 1, the shutter of the deposition shield 101 is closed. Similar to the deposition shield 101, the shutter of the deposition shield 101 is a silicon member made of a silicon-containing material and faces the plasma processing space 10s.

An annular baffle plate 104 having a plurality of vents is disposed inside the plasma processing chamber 10 to surround the substrate support 11. The baffle plate 104 prevents plasma from leaking from the plasma processing space 10s to a gas exhaust port 10e. Similar to the deposition shield 101 and the shutters of the deposition shield 101, the baffle plate 104 is a silicon member made of a silicon-containing material and faces the plasma processing space 10s.

The substrate support 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 in a plan view. The substrate W is disposed on the central region 111a of the main body 111 and the ring assembly 112 is disposed on the annular region 111b of the main body 111 to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one embodiment, the ceramic member 1111a also has the annular region 111b. Other members that surround the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, at least one RF/DC electrode coupled to a radio frequency (RF) power source 31 and/or a direct current (DC) power source 32 to be described below may be disposed inside the ceramic member 1111a. In this case, at least one RF/DC electrode functions as the lower electrode. In a case where the bias RF signal and/or the DC signal to be described later are supplied to at least one RF/DC electrode, the RF/DC electrode is also referred to as a bias electrode. The conductive member of the base 1110 and at least one RF/DC electrode may function as a plurality of lower electrodes. Further, the electrostatic electrode 1111b may function as the lower electrode. Accordingly, the substrate support 11 includes at least one lower electrode.

The ring assembly 112 includes one or more annular members. In one embodiment, one or more annular members include one or more edge rings and at least one cover ring. The edge ring is formed of a conductive material or an insulating material, and the cover ring is formed of an insulating material.

Further, the substrate support 11 may include a temperature control module configured to adjust at least one of the electrostatic chuck 1111, the ring assembly 112, and the substrate to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed inside the base 1110, and one or more heaters are disposed in the ceramic member 1111a of the electrostatic chuck 1111. Further, the substrate support 11 may include a heat transfer gas supply configured to supply a heat transfer gas to a gap between a rear surface of the substrate W and the central region 111a.

The shower head 13 is supported on an upper portion of the plasma processing chamber 10 with an insulating shielding member 105 interposed therebetween. The shower head 13 includes at least one conductive member and functions as an upper electrode. The shower head 13 has an electrode plate 14 and an electrode support 15. Similar to the deposition shield 101, the shutter of the deposition shield 101, and the baffle plate 104, the electrode plate 14 is a silicon member made of a silicon-containing material and faces the plasma processing space 10s. A plurality of gas discharge ports 14a are formed in the electrode plate 14.

The electrode support 15 is, for example, a conductive member made of a conductive material such as aluminum. The electrode support 15 supports the electrode plate 14 in a detachable manner from above. The electrode support 15 is ground for a safety. The electrode support 15 may have a cooling structure (not illustrated). A diffusion chamber 15a is formed in the electrode support 15. A plurality of gas flow ports 15b communicating with the gas discharge ports 14a of the electrode plate 14 extend downward (toward the substrate support 11) from the diffusion chamber 15a. The electrode support 15 is provided with a gas inlet 15c for guiding a processing gas into the diffusion chamber 15a, and the gas supply 20 is connected to the gas inlet 15c through a pipe.

The shower head 13 is configured to introduce at least one processing gas from the gas supply 20 into the plasma processing space 10s. In one embodiment, the shower head 13 is configured to supply at least one processing gas from the gas inlet 15c to the plasma processing space 10s through the diffusion chamber 15a, the gas flow port 15b, and the gas discharge port 14a. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include one or more flow rate modulation devices that modulate or pulse flow rates of at least one processing gas.

The power source 30 includes the radio-frequency (RF) power source 31 coupled to the plasma processing chamber 10 via at least one impedance matching circuit. The RF power source 31 is configured to supply at least one RF signal (RF power) to at least one lower electrode and/or at least one upper electrode. As a result, plasma is formed from at least one processing gas supplied into the plasma processing space 10s. Accordingly, the RF power source 31 may function as at least a portion of a plasma generator configured to generate plasma from one or more processing gases in the plasma processing chamber 10. Further, supplying the bias RF signal to at least one lower electrode can generate a bias potential in the substrate W to attract an ionic component in the formed plasma to the substrate W.

In one embodiment, the RF power source 31 includes a first RF generator 31a and a second RF generator 31b. The first RF generator 31a is configured to be coupled to at least one lower electrode and/or at least one upper electrode via at least one impedance matching circuit to generate a source RF signal (source RF power) for plasma generation. In one embodiment, the source RF signal has a frequency in the range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is configured to be coupled to at least one lower electrode via at least one impedance matching circuit to generate the bias RF signal (bias RF power). A frequency of the bias RF signal may be the same as or different from a frequency of the source RF signal. In one embodiment, the bias RF signal has a lower frequency than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or more bias RF signals are supplied to at least one lower electrode. Further, in various embodiments, at least one of the source RF signal and the bias RF signal may be pulsed.

Further, the power source 30 may include the DC power source 32 coupled to the plasma processing chamber 10. The DC power source 32 includes a first DC generator 32a and a second DC generator 32b. In one embodiment, the first DC generator 32a is configured to be connected to at least one lower electrode to generate the first DC signal. The generated first bias DC signal is applied to at least one lower electrode. In one embodiment, the second DC generator 32b is configured to be connected to at least one upper electrode to generate a second DC signal. The generated second DC signal is applied to at least one upper electrode.

In various embodiments, at least one of the first and second DC signals may be pulsed. In this case, the sequence of voltage pulses is applied to at least one lower electrode and/or at least one upper electrode. The voltage pulse may have a pulse waveform of a rectangle, a trapezoid, a triangle or a combination thereof. In one embodiment, a waveform generator for generating a sequence of voltage pulses from the DC signal is connected between the first DC generator 32a and at least one lower electrode. Accordingly, the first DC generator 32a and the waveform generator configure a voltage pulse generator. In a case where the second DC generator 32b and the waveform generator configure the voltage pulse generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected to, for example, the gas exhaust port 10e disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

The controller 2 processes computer-executable instructions for instructing the plasma processing apparatus 1 to execute various steps described herein below. The controller 2 may be configured to control the respective components of the plasma processing apparatus 1 to execute the various steps described herein below. In an embodiment, part or all of the controller 2 may be included in the plasma processing apparatus 1. The controller 2 may include a processor 2a1, a storage unit 2a2, and a communication interface 2a3. The controller 2 is implemented by, for example, a computer 2a. The processor 2a1 may be configured to read a program from the storage unit 2a2 and perform various control operations by executing the read program. The program may be stored in advance in the storage unit 2a2, or may be acquired via a medium when necessary. The acquired program is stored in the storage unit 2a2, and is read from the storage unit 2a2 and executed by the processor 2a1. The medium may be various storing media readable by the computer 2a, or may be a communication line connected to the communication interface 2a3. The processor 2a1 may be a Central Processing Unit (CPU). The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

In the plasma processing apparatus 1, in order to suppress the generation of particles, a silicon member made of a silicon-containing material may be used as a member facing the plasma processing space 10s. For example, as described above, silicon members are used for the deposition shield 101, the electrode plate 14 of the shower head 13, the baffle plate 104, and the shutter of the deposition shield 101. The silicon-containing material has a higher resistance value than a metal. Therefore, in the plasma processing apparatus 1 in which the silicon member made of a silicon-containing material is used, when the RF power is supplied from the RF power source 31 into the plasma processing space 10s in order to generate plasma, the loss of the RF power in the silicon member may increase.

Therefore, in the plasma processing apparatus 1 according to the embodiment, the conductive film made of a conductive material is formed on the second surface of the silicon member on the side opposite to the first surface facing the plasma processing space 10s. The conductive film may be formed on the entire second surface of the silicon member or may be formed on a portion of the second surface of the silicon member.

As the conductive material configuring the conductive film, for example, aluminum, a nickel alloy, graphene, or the like can be used. The nickel alloy may be, for example, a metal having excellent corrosion resistance such as Hastelloy (registered trademark) or Inconel (registered trademark). Graphene has directivity in conductivity, and has relatively high conductivity in the plane direction. Therefore, when graphene is used for the conductive film, the resistance value of the conductive film in the plane direction is reduced, and the flow of the current is accelerated.

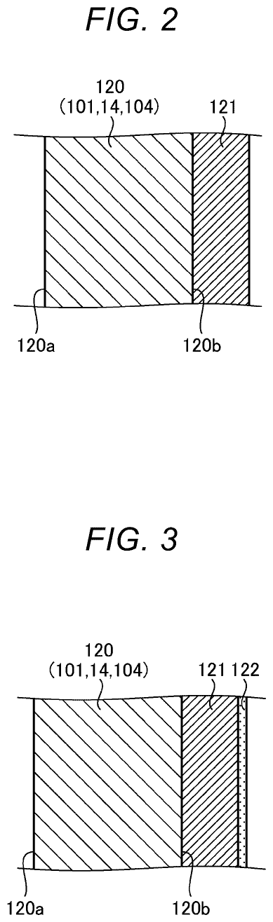

FIG. 2 is a diagram schematically illustrating an example of a structure of a silicon member in an embodiment. A silicon member 120 illustrated in FIG. 2 corresponds to any one of the deposition shield 101, the electrode plate 14 of the shower head 13, the baffle plate 104, and the shutter of the deposition shield 101. The silicon member 120 has a first surface 120a facing the plasma processing space 10s. Then, a conductive film 121 is formed on a second surface 120b on the side opposite to the first surface 120a of the silicon member 120.

Since the conductive film 121 is formed on the second surface 120b of the silicon member 120 on the side opposite to the first surface 120a, the total resistance value decreases due to the combined resistance between the silicon member 120 and the conductive film 121, so that a current due to the RF power easily flows. As a result, it is possible to reduce the loss of the RF power in the silicon member 120. Further, since the first surface 120a of the silicon member 120 faces the plasma processing space 10s, it is possible to suppress the generation of particles due to the metal forming the conductive film 121.

The conductive film 121 is formed by, for example, thermal spraying, chemical vapor deposition (CVD), or physical vapor deposition. The conductive film 121 may have a thickness equal to or more than the skin depth at the frequency of the RF power supplied from the RF power source 31 into the plasma processing space 10s. The skin depth, as known in the art and as defined herewith, refers to the depth at which an alternating current (AC) penetrates a conductor. For example, in a case where the conductive material configuring the conductive film 121 is aluminum, the conductive film 121 may have a thickness of 30 μm or more with respect to the frequency 10 MHz of the RF power, and may have a thickness of 10 μm or more with respect to the frequency 100 MHz of the RF power.

When the thickness of the conductive film 121 is shallower than the skin depth at the frequency of the RF power, the resistance value at the frequency of the RF power increases, which increases the loss of the RF power. Therefore, when the thickness of the conductive film 121 is equal to or more than the skin depth at the frequency of the RF power, the resistance value of the conductive film 121 is reduced, so that the loss of the RF power in the silicon member 120 can be further reduced.

As illustrated in FIG. 3, an anodic oxide film 122 may be formed on the surface of the conductive film 121. FIG. 3 is a diagram schematically illustrating another example of the structure of the silicon member in the embodiment. By covering the surface of the conductive film 121 with the anodic oxide film 122, the conductive film 121 can be protected from the processing gas supplied to the plasma processing space 10s. The anodic oxide film 122 is, for example, a film formed by thermal spraying, chemical vapor deposition (CVD), or physical vapor deposition (PVD). Further, the film formation of the anodic oxide film 122 can be realized by thermal spraying of a compound containing at least one of a silicon-containing film, a group III element, and a lanthanoid element, or coating with a fluororesin.

Next, an example of a specific configuration in which the conductive film 121 is formed on the second surface of the silicon member on the side opposite to the first surface facing the plasma processing space 10s will be described. In the following description, an example of a specific configuration in which the conductive film 121 is formed on the second surface of the deposition shield 101 that is a silicon member will be described.

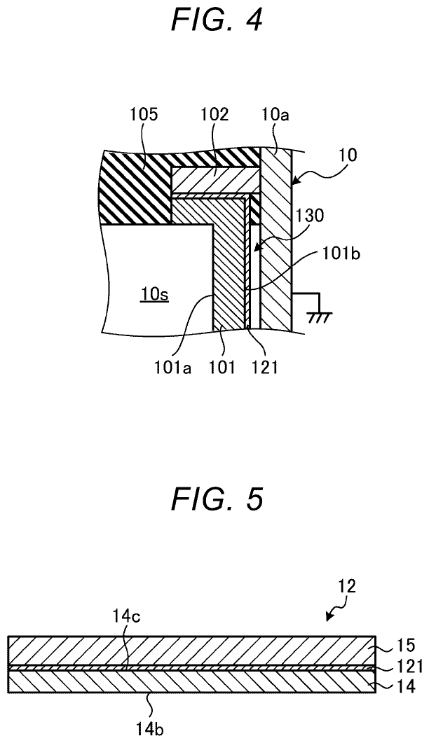

FIG. 4 is a view illustrating an example of a specific configuration of forming the conductive film 121 on the second surface of the deposition shield 101 according to the embodiment. FIG. 4 is an enlarged view of the vicinity of the deposition shield 101.

As illustrated in FIG. 4, in the plasma processing chamber 10, the deposition shield 101 is disposed along the inner wall surface of the sidewall 10a. The deposition shield 101 is disposed with a gap 130 between the sidewall 10a and the deposition shield 101. The deposition shield 101 is a silicon member made of a silicon-containing material and faces the plasma processing space 10s at the first surface 101a. The upper portion of the deposition shield 101 is bent inward in the horizontal direction, and a second surface 101b on the side opposite to the first surface 101a is in contact with the conductive grounding member 102 provided in the sidewall 10a, so as to be electrically conductive with the grounding member 102. In other words, the deposition shield 101 is electrically conductive with the sidewall 10a through the grounding member 102. Since the sidewall 10a is grounded, the deposition shield 101 constitutes an anode electrode by being in contact with the grounding member 102. That is, the deposition shield 101 configures an anode electrode that faces an electrode (for example, a lower electrode or an upper electrode) that is supplied with radio-frequency power from the RF power source 31 via plasma in the plasma processing space 10s.

The conductive film 121 is formed on the second surface 101b on the side opposite to the first surface 101a of the deposition shield 101. In the present embodiment, the conductive film 121 is formed on the entire second surface 101b of the deposition shield 101.

Since the conductive film 121 is formed on the second surface 101b of the deposition shield 101, the total resistance value decreases due to the combined resistance between the deposition shield 101 and the conductive film 121, so that a current due to the RF power easily flows. As a result, it is possible to reduce the loss of the RF power in the deposition shield 101. Further, since the second surface 101b, which is the contact surface with the grounding member 102, is covered with the conductive film 121, it is possible to suppress the increase in contact resistance caused by the formation of a natural oxide film on the second surface 101b. Further, since the resistance value of the second surface 101b decreases, the potential difference between the grounded sidewall 10a and the deposition shield 101 that is the anode electrode decreases to a potential difference less than a limit value at which a discharge is generated, and as a result, it is possible to suppress the occurrence of an abnormal discharge (unintended discharge) in the gap 130.

Further, since the conductive film 121 is formed on the entire second surface 101b of the deposition shield 101, the potential difference between the grounded sidewall 10a and the deposition shield 101 that is the anode electrode can be further reduced, so that the occurrence of an abnormal discharge in the gap 130 can be further suppressed.

In the example of FIG. 4, the conductive film 121 is formed on the entire second surface 101b of the deposition shield 101. However, the conductive film 121 may be formed in a portion of the second surface 101b. In this case, the conductive film 121 may be formed at least in a region of the second surface 101b in contact with the grounding member 102. As a result, it is possible to simplify the process of forming the conductive film 121 while suppressing the occurrence of the abnormal discharge.

Next, another example of a specific configuration in which the conductive film 121 is formed on the second surface of the silicon member on the side opposite to the first surface facing the plasma processing space 10s will be described. In the following description, an example of a specific configuration in which the conductive film 121 is formed on the second surface of the electrode plate 14 that is a silicon member will be described.

FIG. 5 is a view illustrating an example of a specific configuration of forming the conductive film 121 on the second surface of the electrode plate 14 of the shower head 13 according to the embodiment. FIG. 5 is an enlarged view of the shower head 13. In FIG. 5, for the sake of convenience, the gas discharge port 14a, the diffusion chamber 15a, the gas flow port 15b, and the gas inlet 15c are omitted.

As illustrated in FIG. 5, the shower head 13 includes the electrode plate 14 and the electrode support 15. The electrode plate 14 is a silicon member made of a silicon-containing material and faces the plasma processing space 10s at the first surface 14b. The electrode plate 14 is in contact with the conductive electrode support 15 and is electrically conductive with the electrode support 15 on a second surface 14c on the side opposite to the first surface 14b.

The conductive film 121 is formed on the second surface 14c of the electrode plate 14 on the side opposite to the first surface 14b. In the present embodiment, the conductive film 121 is formed on the entire second surface 14c of the electrode plate 14.

Since the conductive film 121 is formed on the second surface 14c of the electrode plate 14, the resistance value of the electrode plate 14 is reduced, so that a current due to the RF power easily flows. As a result, it is possible to reduce the loss of the RF power in the electrode plate 14. Further, since the second surface 14c, which is the contact surface of the electrode support 15, is covered with the conductive film 121, it is possible to suppress the increase of contact resistance caused by the formation of a natural oxide film on the second surface 14c.

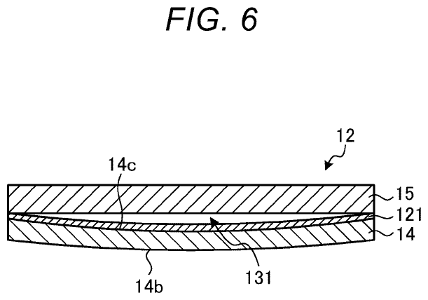

In the shower head 13, the electrode plate 14 or the electrode support 15 may deform due to, for example, the difference in the thermal expansion coefficients of the electrode plate 14 and the electrode support 15, and thus, a gap may be generated between the electrode plate 14 and the electrode support 15. FIG. 6 is a view illustrating an example of the occurrence of a gap in the shower head 13 according to the embodiment. FIG. 6 illustrates a state where a gap is generated in the shower head 13 illustrated in FIG. 5. That is, FIG. 6 illustrates a state where the shower head 13 shifts from a normal temperature state to a high temperature state, whereby the electrode plate 14 is deformed more largely than the electrode support 15, and a gap 131 is generated between the central portion of the electrode plate 14 and the electrode support 15. In this state, the electrode plate 14 is in contact with the conductive electrode support 15 and is electrically conductive with the electrode support 15 only in a region of a peripheral portion that surrounds the central portion of the second surface 14c.

In this way, even when the gap 131 is generated between the electrode plate 14 and the electrode support 15, the second surface 14c, which is a contact surface with the electrode support 15, is covered with the conductive film 121, and the electrode support 15 and the second surface 14c are brought into conduction, so that the potential difference between the electrode plate 14 and the electrode support 15 is reduced. As a result, the potential difference between the electrode plate 14 and the electrode support 15 becomes smaller than the limit value at which a discharge is generated, and as a result, the occurrence of an abnormal discharge in the gap 131 can be suppressed.

In the examples of FIGS. 5 and 6, the conductive film 121 is formed on the entire second surface 14c of the electrode plate 14. However, the conductive film 121 may be formed on a portion of the second surface 14c. In this case, the conductive film 121 may be formed in at least a region (that is, a region of the peripheral portion of the second surface 14c) of the second surface 14c in contact with the electrode support 15 in a state where the gap 131 is formed between the electrode plate 14 and the electrode support 15. As a result, it is possible to simplify the process of forming the conductive film 121 while suppressing the occurrence of the abnormal discharge.

As described above, the plasma processing apparatus (for example, the plasma processing apparatus 1) according to the embodiment includes the chamber (for example, the plasma processing chamber 10), the power source (for example, the RF power source 31), the silicon member (for example, the deposition shield 101, the electrode plate 14 of the shower head 13, the baffle plate 104, and the shutter of the deposition shield 101), and the conductive film (for example, the conductive film 121). The chamber provides a plasma processing space (for example, the plasma processing space 10s). The power source supplies radio-frequency power for generating plasma in the plasma processing space. The silicon member is made of a silicon-containing material, is disposed in the chamber, and has the first surface (for example, first surfaces 101a and 14b) facing the plasma processing space. The conductive film is made of a conductive material and formed on the second surface (for example, the second surfaces 101b and 14c) of the silicon member which does not face the plasma processing space. Accordingly, according to the plasma processing apparatus of the embodiment, it is possible to reduce the loss of the radio-frequency power in the silicon member facing the plasma processing space.

Further, the conductive film according to the embodiment may be formed on the entire second surface of the silicon member. As a result, according to the plasma processing apparatus of the embodiment, it is possible to suppress the occurrence of an abnormal discharge in the gap (for example, the gaps 130 and 131) between the conductive member (for example, the sidewall 10a or the electrode support 15) that faces the second surface of the silicon member and the silicon member.

Further, the conductive film according to the embodiment may be formed in a portion of the second surface of the silicon member. As a result, according to the plasma processing apparatus of the embodiment, the formation process of the conductive film can be simplified while the occurrence of the abnormal discharge is suppressed.

Further, the second surface according to the embodiment may be formed on the side opposite to the first surface of the silicon member. As a result, according to the plasma processing apparatus of the embodiment, it is possible to suppress the occurrence of the abnormal discharge. Further, according to the plasma processing apparatus of the embodiment, the silicon member faces the plasma processing space, so that the generation of particles due to the metal forming the conductive film can be suppressed.

Further, the silicon member according to the embodiment may be in contact with the conductive target member (for example, the grounding member 102 and the electrode support 15) on the second surface so as to be electrically conductive with the conductive target member. Then, the conductive film may be formed in at least a region of the second surface of the silicon member in contact with the conductive target member. As a result, according to the plasma processing apparatus of the embodiment, the formation process of the conductive film can be simplified while the occurrence of the abnormal discharge is suppressed.

Further, the conductive film according to the embodiment may have the thickness equal to or more than the skin depth at the frequency of the radio-frequency power supplied from the power source. Accordingly, according to the plasma processing apparatus of the embodiment, the flow of the current in the silicon member is accelerated and the resistance value of the conductive film is reduced, so that the loss of the RF power in the silicon member can be further reduced.

Further, the conductive material configuring the conductive film according to the embodiment may be aluminum, a nickel alloy, or graphene. Accordingly, according to the plasma processing apparatus of the embodiment, it is possible to reduce the loss of the radio-frequency power in the silicon member facing the plasma processing space.

Further, the plasma processing apparatus according to the embodiment may further have the anodic oxide film formed on the surface of the conductive film. Therefore, the plasma processing apparatus according to the embodiment can protect the conductive film from the processing gas supplied into the plasma processing space.

Further, the silicon member according to the embodiment may configure an anode electrode that faces the electrode that is supplied with the radio-frequency power from the power source via plasma in the plasma processing space. Accordingly, according to the plasma processing apparatus of the embodiment, it is possible to reduce the loss of the radio-frequency power in the anode electrode facing the plasma processing space.

Further, the silicon-containing material configuring the silicon member according to the embodiment may be silicon, silicon carbide, silicon dioxide, or silicon nitride.

Further, the silicon member according to the embodiment may be at least one of the deposition shield, the baffle plate, the electrode plate of the upper electrode, and the shutter disposed along the inner wall surface of the chamber. As a result, according to the plasma processing apparatus of the embodiment, it is possible to reduce the loss of radio-frequency power in the deposition shield, the baffle plate, the electrode plate of the upper electrode, and the shutter.

It shall be understood that the embodiments disclosed herein are illustrative and are not restrictive in all aspects. Indeed, the above-described embodiments can be implemented in various forms. The embodiments described above may be omitted, replaced, or modified in various forms without departing from the scope and spirit of the appended claims.

With respect to the above-described embodiments, the following appendixes will be further disclosed.

### Appendix 1

A plasma processing apparatus including:

a chamber configured to provide a plasma processing space;

a power source configured to supply radio-frequency power for generating plasma into the plasma processing space;

a silicon member made of a silicon-containing material, disposed in the chamber, and having a first surface facing the plasma processing space; and

a conductive film made of a conductive material and formed on a second surface that does not face the plasma processing space of the silicon member.

### Appendix 2

The plasma processing apparatus according to Appendix 1, in which the conductive film is formed on the entire second surface of the silicon member.

### Appendix 3

The plasma processing apparatus according to Appendix 1, in which the conductive film is formed in a portion of the second surface of the silicon member.

### Appendix 4

The plasma processing apparatus according to any one of Appendices 1 to 3, in which the second surface is formed on a side opposite to the first surface.

### Appendix 5

The plasma processing apparatus according to Appendix 4, in which the silicon member is in contact with a conductive target member on the second surface to be electric ally conductive with the conductive target member, and the conductive film is formed in at least a region of the second surface of the silicon member in contact with the conductive target member.

### Appendix 6

The plasma processing apparatus according to any one of Appendices 1 to 5, in which the conductive film has a thickness equal to or more than a skin depth at a frequency of the radio-frequency power supplied from the power source.

### Appendix 7

The plasma processing apparatus according to any one of Appendices 1 to 6, in which the conductive material configuring the conductive film is aluminum, a nickel alloy, or graphene.

### Appendix 8

The plasma processing apparatus according to any one of Appendices 1 to 7, further including an anodic oxide film formed on a surface of the conductive film.

### Appendix 9

The plasma processing apparatus according to any one of Appendices 1 to 8, in which the silicon member configures an anode electrode that faces an electrode supplied with the radio-frequency power from the power source via plasma in the plasma processing space.

### Appendix 10

The plasma processing apparatus according to any one of Appendices 1 to 9, in which the silicon-containing material configuring the silicon member is silicon, silicon carbide, silicon dioxide, or silicon nitride.

### Appendix 11

The plasma processing apparatus according to any one of Appendices 1 to 10, in which the silicon member is at least one of a deposition shield, a baffle plate, an electrode plate of an upper electrode, and a shutter disposed along an inner wall surface of the chamber.

1. A plasma processing apparatus comprising:
a chamber including a plasma processing space;
a power source configured to supply radio-frequency power for generating plasma into the plasma processing space;
a silicon member made of a silicon-containing material, the silicon member being disposed in the chamber, and having a first surface facing the plasma processing space; and
a conductive film made of a conductive material, the conductive film being formed on a second surface that does not face the plasma processing space of the silicon member.

2. The plasma processing apparatus according to claim 1, wherein the conductive film is formed on the entire second surface of the silicon member.

3. The plasma processing apparatus according to claim 1, wherein the conductive film is formed on a portion of the second surface of the silicon member.

4. The plasma processing apparatus of claim 1, wherein the second surface is formed on a side opposite to the first surface.

5. The plasma processing apparatus according to claim 4, wherein
the silicon member is in contact with a conductive target member on the second surface to be electrically connected with the conductive target member, and
the conductive film is formed in at least a region of the second surface of the silicon member in contact with the conductive target member.

6. The plasma processing apparatus according to claim 1, wherein the conductive film has a thickness equal to or more than a skin depth at a frequency of the radio-frequency power supplied from the power source.

7. The plasma processing apparatus according to claim 1, wherein the conductive material of the conductive film includes aluminum, a nickel alloy, or graphene.

8. The plasma processing apparatus according to claim 1, further comprising an anodic oxide film formed on a surface of the conductive film.

9. The plasma processing apparatus according to claim 1, wherein the silicon member is in the form of an anode electrode that faces an electrode supplied with the radio-frequency power from the power source via plasma in the plasma processing space.

10. The plasma processing apparatus according to claim 1, wherein the silicon-containing material includes silicon, silicon carbide, silicon dioxide, or silicon nitride.

11. The plasma processing apparatus according to claim 1, wherein
the silicon member is at least one of a deposition shield, a baffle plate, an electrode plate of an upper electrode, and a shutter, and
the silicon member is disposed along an inner wall surface of the chamber.

12. The plasma processing apparatus according to claim 1, wherein
the silicon member is in the form of a deposition shield, and
a gap is provided between the deposition shield and a sidewall of the chamber.

13. The plasma processing apparatus according to claim 12, further comprising:
a shower head configured to discharge processing gas to the plasma processing space;
an insulating shielding member disposed between the shower head and the chamber; and
a conductive grounding member disposed between the silicon member and the insulating shielding member.

14. The plasma processing apparatus according to claim 13, wherein
the silicon member forms an L-shape and forms two surfaces of the plasma processing space.

15. The plasma processing apparatus according to claim 1, further comprising a shower head configured to discharge processing gas to the plasma processing space, wherein
the shower head includes the silicon member and an electrode support,
the silicon member is in the form of an electrode plate, and
the conductive film is disposed between the electrode plate and the electrode support of the shower head.

16. A plasma processing apparatus comprising:
a chamber including a plasma processing space;
a power source configured to supply radio-frequency power for generating plasma into the plasma processing space;
a silicon member made of a silicon-containing material, the silicon member being disposed in the chamber, and having a first surface facing the plasma processing space;
a conductive film made of a conductive material, the conductive film being formed on a second surface that does not face the plasma processing space of the silicon member; and
an anodic oxide film formed on a surface of the conductive film, the anodic film being configured to protect the silicon member from a processing gas.

17. The plasma processing apparatus of claim 16, further comprising a shower head configured to discharge processing gas to the plasma processing space,
wherein the shower head includes the silicon member and an electrode support.

18. The plasma processing apparatus of claim 17, wherein
the silicon member is in the form of an electrode plate, and
the conductive film is disposed between the electrode plate and the electrode support of the shower head.

19. The plasma processing apparatus of claim 16, wherein
the silicon member is in the form of a deposition shield, and
a gap is provided between the deposition shield and a sidewall of the processing chamber.

20. The plasma processing apparatus of claim 16, further comprising:
an insulating shielding member; and
a conductive grounding member disposed between the silicon member and the insulating shielding member,
wherein the silicon member forms an L-shape and forms two surfaces of the plasma processing space.
